(19) United States
(12) Patent Application Publication
(10) Pub. No.: US 2026/0005044 A1
(43) Pub. Date: Jan. 1, 2026

(54) REFLECTOR ASSEMBLIES FOR SUBSTRATE PROCESSING ADJUSTABILITY, AND RELATED PROCESS CHAMBERS, METHODS, AND SYSTEMS

(71) Applicant: Applied Materials, Inc., Santa Clara, CA (US)

(72) Inventors: Michael R. RICE, Pleasanton, CA (US); Kim Ramkumar VELLORE, San Jose, CA (US); Shu-Kwan LAU, Sunnyvale, CA (US); Kalaivanan MOHANADASS, Santa Clara, CA (US); Sushant Suresh KOSHTI, Sunnyvale, CA (US); Martin Jeffrey SALINAS, San Jose, CA (US); Paul BRILLHART, Pleasanton, CA (US)

(21) Appl. No.: 19/231,136

(22) Filed: Jun. 6, 2025

Related U.S. Application Data
(60) Provisional application No. 63/666,062, filed on Jun. 28, 2024.
(60) Provisional application No. 63/684,852, filed on Aug. 19, 2024.

(51) Int. Cl. H01L 21/67; G02B 26/12; H01L 21/66; H05B 3/00

(52) U.S. Cl. CPC H01L 21/67115; G02B 26/12; H01L 21/67248; H01L 22/12; H05B 3/0038

(57) ABSTRACT

The present disclosure relates to reflector assemblies for substrate processing adjustability in semiconductor manufacturing, and related process chambers, methods, and systems. In one or more embodiments, a process chamber includes a chamber body at least partially defining a processing volume, a substrate support disposed in the processing volume, and a heat assembly disposed outwardly of the processing volume. The heat assembly is operable to direct radiation to a target location in the processing volume. The heat assembly includes a reflector pivotable relative to an axis to move the target location and scan the radiation, and a radiation source oriented to emit radiation toward the reflector.

### CROSS-REFERENCE TO RELATED APPLICATIONS

This application claims the benefit of U.S. Provisional Patent Application Ser. No. 63/684,852, filed Aug. 19, 2024, and U.S. Provisional Patent Application Ser. No. 63/666,062, filed Jun. 28, 2024, which are herein incorporated herein by reference in their entireties.

### BACKGROUND

### Field

The present disclosure relates to reflector assemblies for substrate processing adjustability in semiconductor manufacturing, and related process chambers, methods, and systems.

### Description of the Related Art

Semiconductor substrates are processed for a wide variety of applications, including the fabrication of integrated devices and microdevices. During processing, various parameters can affect the uniformity of material deposited on the substrate. For example, the temperature of the substrate and/or temperature(s) of processing chamber component(s) can affect deposition uniformity.

It can be difficult to adjust parameters (such as temperature) for deposition uniformity. Precise control over a heating source allows a substrate to be heated within tolerances. The temperature of the substrate can affect the uniformity of the material deposited on the substrate. For example, film thickness non-uniformities can occur across a substrate in a non-uniform manner. It can be difficult to adjust process parameters, such as temperature and/or film growth. Adjustments can also involve opening of the process chamber and machine down time. Despite control of substrate heating, valleys (lower deposition) can form at certain locations on substrates. Therefore, there is a need for apparatus and methods for improving heating uniformity.

Therefore, a need exists for improved processing chambers and related components that facilitate temperature adjustability and deposition adjustability.

### SUMMARY

The present disclosure relates to reflector assemblies for substrate processing adjustability in semiconductor manufacturing, and related process chambers, methods, and systems.

In one or more embodiments, a process chamber includes a chamber body at least partially defining a processing volume, a substrate support disposed in the processing volume, and a heat assembly disposed outwardly of the processing volume. The heat assembly is operable to direct radiation to a target location in the processing volume. The heat assembly includes a reflector pivotable relative to an axis to move the target location and scan the radiation, and a radiation source oriented to emit radiation toward the reflector.

In one or more embodiments, a process chamber includes a chamber body at least partially defining a processing volume, a substrate support disposed in the processing volume, and a heat assembly disposed outwardly of the processing volume. The heat assembly includes a polygonal reflector pivotable relative to an axis, and a radiation source oriented to emit radiation toward at least one outer surface of the polygonal reflector. The polygonal reflector is oriented to reflect the radiation to a target location in the processing volume. The polygonal reflector is pivotable to move the target location.

In one or more embodiments, a method of monitoring substrate processing includes measuring a parameter of substrate processing, and determining if a parameter difference exceeds a threshold. The parameter difference corresponds to a location in a processing volume of a process chamber. The method includes adjusting a heat assembly if the parameter difference exceeds a threshold. The heat assembly includes a reflector pivotable relative to an axis, and a radiation source oriented to emit radiation toward the reflector.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic side view of a heat assembly, according to one or more embodiments.

FIG. 3 is a schematic top view of the heat assembly, according to one or more embodiments.

FIG. 4 is a schematic side view of a heat assembly, according to one or more embodiments.

FIG. 5 is a schematic top view of a reflector plate, according to one or more embodiments.

FIG. 6 is a schematic top view of a reflector plate, according to one or more embodiments.

FIG. 7 is a schematic plan view of a spot path of radiation emitted by the heat assembly shown in FIGS. 2 and 3, according to one or more embodiments.

FIG. 8 is a schematic plan view of a spot path of radiation emitted by the heat assembly shown in FIGS. 2 and 3, according to one or more embodiments.

FIG. 9 is a schematic graphical view of a film thickness profile of a processed substrate.

FIG. 10 is a schematic flow diagram view of a method of monitoring substrate processing, according to one or more embodiments.

FIG. 11 is a schematic side cross-sectional view of a processing chamber, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to pre-heat rings including carbon heaters, and related heating systems, methods and processing chambers for semiconductor manufacturing.

The disclosure contemplates that terms such as “couples,” “coupling,” “couple,” and “coupled” may include but are not limited to embedding, bonding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

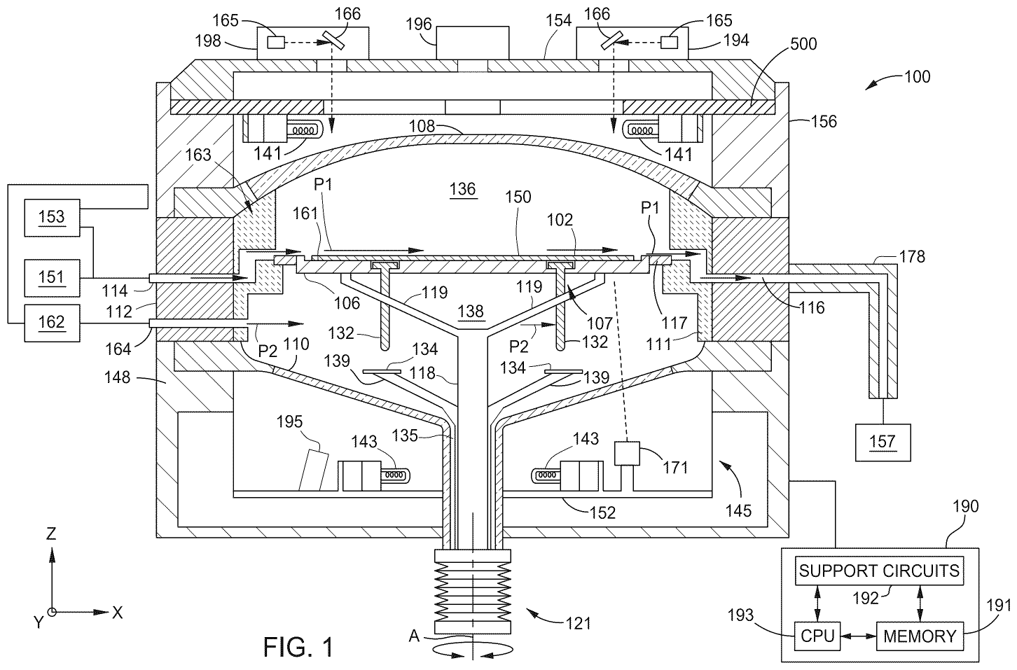

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper plate 108 (such as an upper window, for example an upper dome), a lower plate 110 (such as a lower window, for example a lower dome), a plurality of upper heat sources 141, and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper plate 108 and the lower plate 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper plate and a lid plate 154. The plurality of upper heat sources 141 form a portion of the upper heat source module 155. The arrays of heat sources 141, 143 can be independently controlled in zones in order to control the temperature of various regions of the substrate 102 as the process gas passes thereover, thus facilitating the deposition of a material onto the upper surface of the substrate 102. While not discussed here in detail, the deposited material may include silicon, doped silicon, germanium, doped germanium, silicon germanium, doped silicon germanium, gallium arsenide, gallium nitride, or aluminum gallium nitride, among other materials.

The plurality of lower heat sources 143 are disposed between the lower plate 110 and a floor 152. The plurality of lower heat sources 143 form a portion of a lower heat source module 145. The upper plate 108 is an upper dome and/or is formed of an energy transmissive material, such as quartz. The lower plate 110 is a lower dome and/or is formed of an energy transmissive material, such as quartz.

A processing volume 136 and a purge volume 138 are formed between the upper plate 108 and the lower plate 110. The processing volume 136 and the purge volume 138 are part of an internal volume defined at least partially by the upper plate 108, the lower plate 110, and one or more liners 111, 163 of the chamber body. In one or more embodiments, the processing volume 136 is a processing volume.

The internal volume has the substrate support 106 disposed therein. The substrate support 106 includes a top surface 161 on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116.

A pre-heat ring 117 is disposed below the one or more gas inlets 114 and the one or more gas exhaust outlets 116. The pre-heat ring 117 is disposed above the one or more purge gas inlets 164. The pre-heat ring 117 is disposed at least partially outwardly of the substrate support 106. The one or more liners 111, 163 are disposed on an inner surface of the flow module 112 and protect the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (CI). In one or more embodiments, the one or more process gases P1 include one or more silicon-containing gases (such as silane and/or silicon phosphide (SiP)) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

The processing chamber 100 includes the one or more liners 111, 163 (e.g., a lower liner 111 and an upper liner 163). The lower liner 111 and the upper liner 163 are disposed inwardly of a sidewall (e.g., the flow module 112 and/or the upper body 156) of the chamber body. The flow module 112 (which can be at least part of the sidewall of the processing chamber 100) includes the one or more gas inlets 114 in fluid communication with the processing volume 136. The one or more gas inlets 114 are in fluid communication with one or more flow gaps between the upper liner 163 and a lower liner 111. The one or more of the liners 111, 163 include one or more ledges supporting the pre-heat ring 117.

One or more heat assemblies 194, 198 (two are shown) are used in addition to the heat sources 141, 143. The one or more heat assemblies 194, 198 respectively include a radiation source 165 (such as a laser source) and one or more reflectors 166 (one is shown in FIG. 1). In one or more embodiments, the radiation source 165 is a galvanometer laser source. The processing chamber 100 includes a controller 190 in communication with the one or more heat assemblies 194, 198. The controller 190 can control power to the one or more heat assemblies 194, 198 in an open-loop manner or a closed-loop manner. For example, the closed-loop manner can account for a substrate map (such as a metrology map, a temperature map, a dopant map, and/or a deposition map) for the current processing chamber 100 and/or a substrate map for a previous processing iteration. As another example, the closed-loop manner can account for real-time temperature measurements of at least one of one or more sensors 195, 196.

The controller can receive the temperature measurements of the temperature sensors 195-198 and control (such as alter) the power supplied to the one or more heat assemblies 194, 198 to control (such as adjust) the temperature of one or more portions of the substrate 102. As an example, the controller can compare measured temperature(s) of the substrate 102 to a target temperature and adjust the power supplied to the one or more heat assemblies 194, 198 based on the target temperature. The target temperature can be stored in a memory (such as the memory 191 of the controller 190 described below). A lower heat assembly 171 (similar to the one or more heat assemblies 194, 198) can be disposed below the lower plate 110.

During a deposition operation (e.g., an epitaxial growth operation), the one or more process gases P1 flow through the one or more gas inlets 114, through the one or more gaps, and into the processing volume 136 to flow over the substrate 102. During the deposition operation, the one or more heat assemblies 194, 198 are used to heat a portion of the substrate 102. The one or more process gases P1 flow over the pre-heat ring 117, which pre-activates the one or more process gases P1 for depositing film on the substrate 102 prior to flowing over the substrate 102. The heating using the one or more heat assemblies 194, 198 facilitates deposition of film at an outer region (such as an edge region) of the substrate 102, which facilitates deposition uniformity (such as center-to-edge uniformity). The one or more heat assemblies 194, 198 facilitates deposition uniformity while facilitating reduced particle contamination of the substrate 102 and/or reduced degradation of chamber components.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

The processing system includes one or more sensors 195, 196 (e.g., temperature sensors) configured to measure parameter(s) (e.g., temperature(s)) within the processing chamber 100. In one or more embodiments, the one or more sensors 195, 196 include a central sensor 196 and one or more outer sensors 195. The controller 190 (described below) can control the one or more sensors 195, 196, the one or more heat assemblies 194, 198, and/or one or more heat sources 141, 143, and can conduct method(s) of adjusting uniformity of substrate processing using at least one of the one or more sensors 195, 196, the one or more heat assemblies 194, 198, and/or one or more heat sources 141, 143. In one or more embodiments, one or more sensors 195, 196 each include a pyrometer, such as a pyrometer that includes a silicon sensor. In one or more embodiments, each sensor 195, 196 is an optical sensor, such as an optical pyrometer. The present disclosure contemplates that sensors other than pyrometers may be used, and/or one or more of the sensors 195, 196 can measure properties other than temperature. In one or more embodiments, one or more sensors 195, 196 each include an infrared (IR) camera, such as a line scan IR camera.

In one or more embodiments, the sensors 195, 196 include one or more upper sensors 196 disposed above the substrate 102 and adjacent the lid plate 154, and one or more lower sensors 195 disposed below the substrate 102 and adjacent the floor 152. The present disclosure contemplates that at least one of the one or more lower sensors 195 can be vertically aligned below at least one of the upper sensors 196, 196.

Each sensor 195, 196 can be a single-wavelength sensor device or a multi-wavelength (such as dual-wavelength) sensor device. In one or more embodiments, the system including the process chamber 100 includes any one, any two, or any three of the four illustrated sensors 195, 196. In one or more embodiments, the process chamber 100 includes one or more additional sensors, in addition to the sensors 195, 196. The process chamber 100 may include sensors disposed at different locations and/or with different orientations than the illustrated sensors 195, 196. The one or more heat assemblies 194, 198 and/or one or more similar heat sources can be disposed at different locations and/or with different orientations than the illustrated sensors 195, 196.

As shown, a controller 190 is in communication with the processing chamber 100 and is used to control processes and methods, such as the operations of the methods described herein.

The controller 190 is configured to receive data or input as sensor readings from sensor(s) (such as one or more of the sensors 195, 196) and/or as inputs from other devices. For example, the controller 190 can receive the data from another tool (such as another processing chamber) in the form of incoming substrate reading maps (e.g., including critical dimension data, feature depth data, in-substrate uniformity, or other incoming substrate data, such as other feature geometry features). The controller 190 can account for variations in the substrate reading maps across multiple substrates. The sensors can include, for example: sensors that monitor growth of layer(s) on the substrate 102; and/or sensors that monitor temperatures of the substrate 102, the substrate support 106, and/or the liners 111, 163. The controller 190 is equipped with or in communication with a system model of the processing chamber 100. The system model includes a heating model, a temperature uniformity model, a film uniformity model, a film deposition rate model, a coating model, a rotational position model, and/or a gas flow model. The system model is a program configured to estimate parameters (such as a signal profile (e.g., a temperature profile) of the substrate 102 and/or the substrate support 106, a gas flow rate, a gas pressure, a rotational position of component(s), a heating profile, a coating condition, and/or a cleaning condition) within the processing chamber 100 throughout a deposition operation and/or a cleaning operation. The controller 190 is further configured to store readings and calculations. The readings and calculations include previous sensor readings, such as any previous sensor readings within the processing chamber 100. The readings and calculations further include the stored calculated values from after the sensor readings are measured by the controller 190 and run through the system model. Therefore, the controller 190 is configured to both retrieve stored readings and calculations as well as save readings and calculations for future use. Maintaining previous readings and calculations enables the controller 190 to adjust the system model over time to reflect a more accurate version of the processing chamber 100.

The controller 190 can monitor heating, generate a signal profile (e.g., a temperature profile), identify set(s) of one or more heat sources, adjust a heating profile, adjusting heating power(s) (such as the power supplied to the one or more heat assemblies 194, 198), estimate an optimized parameter (such as the target temperature), adjust the one or more sensors 195, 196, generate an alert on a display, halt a deposition operation, initiate a chamber downtime period, delay a subsequent iteration of the deposition operation, initiate a cleaning operation, halt the cleaning operation, and/or otherwise adjust the process recipe.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., target temperature(s) for the substrate 102, reading(s), signal difference(s), signal profile(s), heating power(s) (e.g., applied to the one or more heat assemblies 194, 198 and/or one or more of the heat sources 141, 143), adjustment factor(s), threshold ratio(s), range(s) and/or training range(s) with which the signal difference(s) are compared, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of the operations described herein (such as the deposition operation) to be conducted in relation to the processing chamber 100. The controller 190 and the processing chamber 100 are at least part of a system for processing substrates.

The various operations described herein (such as operations of the method 1000) can be conducted automatically using the controller 190, or can be conducted automatically or manually with certain operations conducted by a user.

In one or more embodiments, the controller 190 includes a mass storage device, an input control unit, and a display unit. The controller 190 can monitor the temperature of the substrate 102, the temperature of the substrate support 106, the process gas flow, and/or the purge gas flow. In one or more embodiments, the controller 190 includes multiple controllers 190, such that the stored readings and calculations and the system model are stored within a separate controller from the controller 190 which controls the operations of the processing chamber 100. In one or more embodiments, all of the system model and the stored readings and calculations are saved within the controller 190.

The controller 190 is configured to control the deposition, the cleaning, the rotational position, the heating, and gas flow through the processing chamber 100 by providing an output to the controls for the sensors 195, 196, the one or more heat assemblies 194, 198, the upper heat sources 141, the lower heat sources 143, the process gas source 151, the purge gas source 162, the motion assembly 121, and/or the exhaust pump 157.

The controller 190 is configured to adjust the output to the controls based on the sensor readings, the system model, and the stored readings and calculations. The controller 190 includes embedded software and a compensation algorithm to calibrate measurements. The controller 190 can include one or more machine learning algorithms and/or artificial intelligence algorithms that estimate optimized parameters (such as the target temperature(s) for the substrate 102) for the uniformity analysis operations, the deposition operations, and/or the cleaning operations.

The one or more machine learning algorithms and/or artificial intelligence algorithms may implement, adjust and/or refine one or more algorithms, inputs, outputs or variables described above. Additionally or alternatively, the one or more machine learning algorithms and/or artificial intelligence algorithms may rank or prioritize certain aspects of adjustments of the process chamber 100 and/or method(s) relative to other aspects of the process chamber 100 and/or method(s) (such as the method 1000). The one or more machine learning algorithms and/or artificial intelligence algorithms may account for other changes within the processing systems such as hardware replacement and/or degradation. In one or more embodiments, the one or more machine learning algorithms and/or artificial intelligence algorithms account for upstream or downstream changes that may occur in the processing system due to variable changes of the process chamber 100 and/or method(s). For example, if variable “A” is adjusted to cause a change in aspect “B” of the process, and such an adjustment unintentionally causes a change in aspect “C” of the process, then the one or more machine learning algorithms and/or artificial intelligence algorithms may take such a change of aspect “C” into account. In such an embodiment, the one or more machine learning algorithms and/or artificial intelligence algorithms embody predictive aspects related to implementing the process chamber 100 and/or the method(s). The predictive aspects can be utilized to preemptively mitigate unintended changes within a processing system.

The one or more machine learning algorithms and/or artificial intelligence algorithms can use, for example, a regression model (such as a linear regression model) or a clustering technique to estimate optimized parameters. The algorithm can be unsupervised or supervised. The one or more machine learning algorithms and/or artificial intelligence algorithms can optimize, for example, optimized parameters such as target temperature(s), reading(s), signal difference(s), signal profile(s), heating power(s), adjustment factor(s), threshold ratio(s), range(s), and/or training range(s) with which the signal difference(s) are compared, a cleaning recipe, and/or a processing recipe.

In one or more embodiments, the controller 190 automatically conducts the operations described herein without the use of one or more machine learning algorithms and/or artificial intelligence algorithms. In one or more embodiments, the controller 190 compares measurements (such as readings and/or signal differences for temperature measurements) to data in a look-up table and/or a library to identify a set of one or more heat sources and/or adjust a heating power for the one or more heat assemblies 194, 198. The controller 190 can stored measurements as data in the look-up table and/or the library.

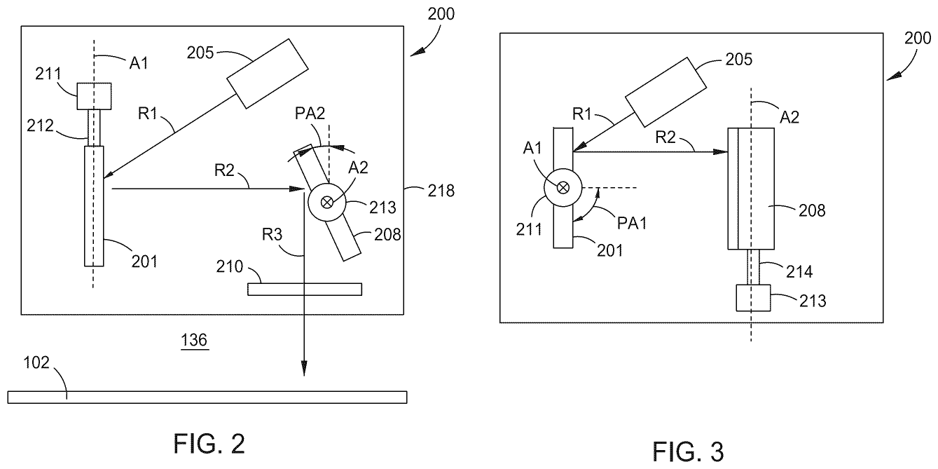

FIG. 2 is a schematic side view of a heat assembly 200, according to one or more embodiments.

FIG. 3 is a schematic top view of the heat assembly 200, according to one or more embodiments.

FIGS. 2 and 3 are described together. The heat assembly 200 can be used as one or more of the one or more heat assemblies 194, 198 and/or the lower heat assembly 171 shown in FIG. 1. The heat assembly 200 includes a first reflector 201 pivotable relative to a first axis A1, and a radiation source 205 oriented to emit radiation R1 toward the first reflector 201. The radiation R1 reflects off of the first reflector 201 as a reflected radiation R2. The heat assembly 200 includes a second reflector 208 oriented to receive the reflected radiation R2 from the first reflector 201 and reflect the reflected radiation R2 as emitted radiation R3 to a target location in the processing volume 136. The second reflector 208 pivotable relative to a second axis A2. The second axis A2 is oriented nonparallel to the first axis A1. For example, the second axis A2 can be orthogonal, offset, and/or tangential to the first axis A1. The heat assembly 200 includes one or more lenses 210 that focus and/or collimate the emitted radiation R3. In one or more embodiments, the first reflector 201 includes a first mirror (such as a galvanometer mirror), and the second reflector 208 includes a second mirror (such as a galvanometer mirror). Although two reflectors 201, 208 are shown, a variety of numbers of reflectors are contemplated. For example, one reflector, three reflectors, four reflectors, or another number of reflectors can be used.

The heat assembly 200 includes a first actuator 211 including a first link 212 coupled to the first reflector 201 along the first axis A1. The first actuator 211 pivots the first reflector 201 to move the target location azimuthally along the substrate 102, and the second actuator 213 pivots the second reflector 208 to move the target location radially along the substrate 102. The heat assembly 200 includes a second actuator 213 including a second link 214 coupled to the second reflector 208 along the second axis A2. In one or more embodiments, the first actuator 211 and the second actuator 213 respectively include a motor, such as a galvanometer motor, a stepper motor, a rotating actuator, and/or a linear actuator. In one or more embodiments, the motor is a high speed motor. In one or more embodiments, the motor moves (e.g., scans) a spot of heating energy at a speed up to 25 meters per second, such as a speed within a range of 20 meters per second to 25 meters per second.

The controller 190 is operable to control the heat assembly 200 based on a parameter (such as temperature) of the target location that is measured by at least one of the one or more sensors 195, 196. The controller 190 causes an input to be adjusted based on the parameter. In one or more embodiments, the input includes one or more of a first position angle PA1 for the first reflector 201, or a second position angle PA2 for the second reflector 208. In one or more embodiments, the input includes one or more of a first angular velocity for the first reflector, or a second angular velocity for the first reflector. In one or more embodiments, the input includes one or more of a dwell time, a radiation power (such as a laser power) for the radiation source, or a pulse frequency for the radiation source. In such an embodiment, the energy to locations on the substrate can be varied by one or more of dwell time, energy source power, or source pulse frequency. The controller 190 is configured to determine if a parameter difference (such as a temperature difference and/or a film thickness difference) exceeds a threshold, and adjust the input if the parameter difference exceeds the threshold. The processing chamber 100 includes the lid plate 154 disposed outwardly of the processing volume 136. In one or more embodiments, the heat assembly 200 includes a reflector housing 218 mounted to the lid plate 154 (FIG. 1).

The radiation source 205 can be an electromagnetic radiant source, and/or can be coupled to optical fibers. The electromagnetic radiant source may be a pulsing electromagnetic radiant source or a continuous wave (CW) electromagnetic radiant source.

The electromagnetic radiant source may be a high-energy radiant source, such as a laser. Examples of laser sources that may be used include crystal lasers, laser diodes and arrays, and VCSEL's. High intensity LED sources may also be used, and collimators may be used to collimate light emitted from the LED source to form a light beam. Wavelength of the emitted radiation may generally be in the ultraviolet, visible, and/or infrared spectrum, from about 200 nm to about 900 nm, for example 810 nm, and the emitted radiation may be monochromatic, narrow band, broadband, or ultra-broadband such as a white laser. The radiation source 205 can emit high intensity electromagnetic radiation, which can be routed through fibers to emit a radiant beam. An end of the optical fiber(s) can have one or more optical features, including lenses, faceted surfaces, diffuse surfaces, filters and other coatings, to direct or condition the electromagnetic radiation exiting the fiber. Alternately, one or more optical elements can be coupled to the end of the optical fiber(s). The radiation source 205 is thus configurable and swappable. The radiant beams from the radiation source 205 may have the same wavelength or different wavelengths. In one or more embodiments, the radiant beams have different wavelengths for heating different materials formed on the substrate 102.

In one or more embodiments, the heat assembly 200 is a spot heater capable of rasterizing the substrate 102. For example, the rasterization can induce and/or correct non-uniformities in substrate maps.

Power density of the radiation source 205 may range from about 1 W/cm2 to about 1000 W/cm2, for example about 1 W/cm2 to about 200 W/cm2, for example about 200 W/cm2 to about 1000 W/cm2. Each heat assembly 194, 198 is coupled to and disposed on an upper surface of the lid plate 154, and directs radiant energy through an opening of the lid plate 154 (which may have an optically transparent window therein) of the lid plate 154. Radiant energy from each heat assembly 194, 198 is directed towards the substrate support 106 in order to impinge upon one or more predetermined locations of the substrate 102. The radiant energy selectively heats predetermined locations of the substrate, resulting in more uniform substrate temperature (and thus more uniform deposition) during processing. The thermal energy provided by each heat assembly 194, 198 is directed to a location on the substrate 102 in response to temperature measurements by the sensor 196 and one or more instructions from the controller 190.

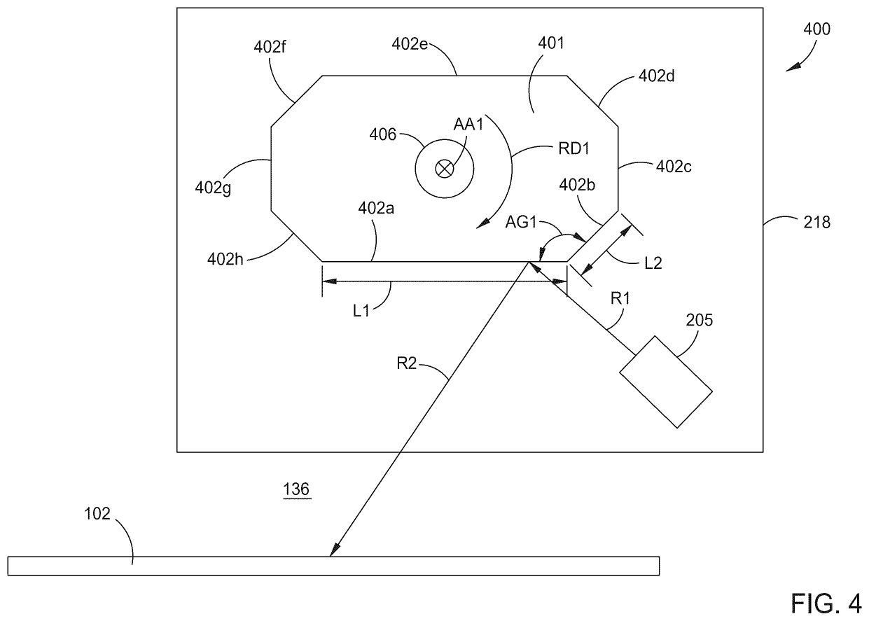

FIG. 4 is a schematic side view of a heat assembly 400, according to one or more embodiments.

The heat assembly 400 can be used as one or more of the one or more heat assemblies 194, 198 and/or the lower heat assembly 171 shown in FIG. 1. Although three heat assemblies 194, 198, 171 are shown in FIG. 1, a difference number of heat assemblies can be used. The heat assembly 400 includes a polygonal reflector 401 pivotable relative to an axis AA1, and the radiation source 205. In one or more embodiments, the polygonal reflector 401 includes a prism. The radiation source 205 is oriented to emit radiation R1 toward at least one outer surface 402 of the polygonal reflector 401. The polygonal reflector 401 includes a plurality of outer surfaces 402a-402h, and at least two of the outer surfaces have differing lengths (such as a first length L1 and a second length L2). In one or more embodiments, the at least one outer surface 402 is a mirror surface. The mirror surface can include, for example, a gold surface and/or a polished aluminum surface. Other mirror surfaces are contemplated.

The polygonal reflector 401 is oriented to reflect the radiation R1 (as reflected radiation R2) to a target location in the processing volume 136. The axis AA1 extends parallel to a plane of the at least one outer surface 402. In one or more embodiments, the polygonal reflector 401 is rotatable about the axis AA1. For example, an actuator 406 can pivot the polygonal reflector 401 along a rotational direction RD1. The pivoting of the polygonal reflector 401 aligns a different outer surface 402 with the radiation R1.

For example, the pivoting of the polygonal reflector 401 moves an incidence of the radiation R1 from a first outer surface 402a of the reflector 401 to a second outer surface 402b of the reflector 401. The second outer surface 402b is oriented at an angle AG1 relative to the first outer surface 402a. The axis AA1 extends through two opposing outer surfaces 402 of the polygonal reflector 401.

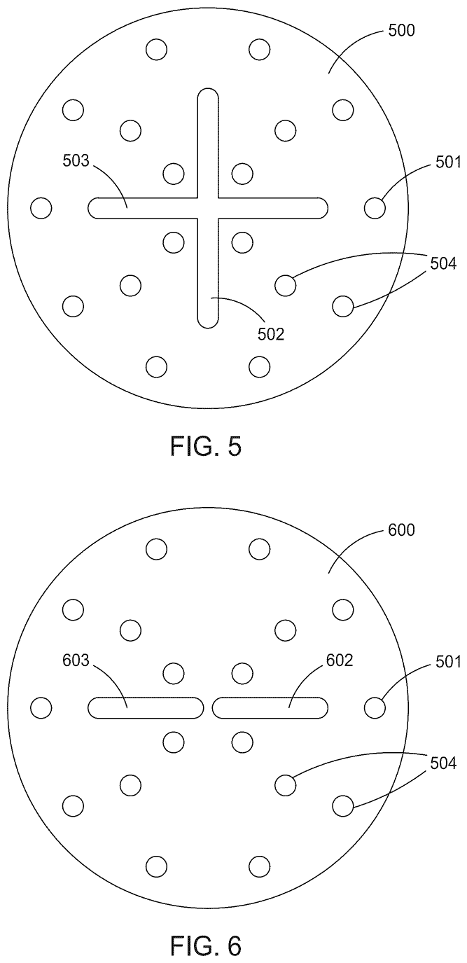

FIG. 5 is a schematic top view of a reflector plate 500, according to one or more embodiments.

The reflector plate 500 includes a first opening 502 (such as a first slot) and a second opening 503 (such as a second slot). The one or more heat assemblies 194, 198 can be positionable to emit radiation through the first opening 502 and/or the second opening 503, and the sensor 196 can be positionable to measure temperature through the first opening 502 and/or the second opening 503. The openings 502, 503 can intersect each other. The reflector plate 500 includes connector openings 504, and the heat sources 141 can be connected to power through the connector openings 504.

The present disclosure contemplates that four heat assemblies (similar to the heat assemblies 194, 198) can be respectively aligned with the four lobes of the openings 502, 503. The present disclosure contemplates that two or more of the heat assemblies can be disposed at different radial positions relative to a center of the reflector plate 500. The present disclosure also contemplates that any number of heat assemblies can be used.

FIG. 6 is a schematic top view of a reflector plate 600, according to one or more embodiments.

The reflector plate 600 is similar to the reflector plate 500, and includes one or more aspects, features, components, properties, and/or operations thereof. The reflector plate 600 includes a first opening 602 (such as a first slot) and a second opening 603 (such as a second slot). At least part of the reflector plate 600 can separate the first and second openings 602, 603. The heat assembly 194 can be positionable to emit radiation through the first opening 602. The heat assembly 198 and the sensor 196 can be positionable to emit radiation through the second opening 603.

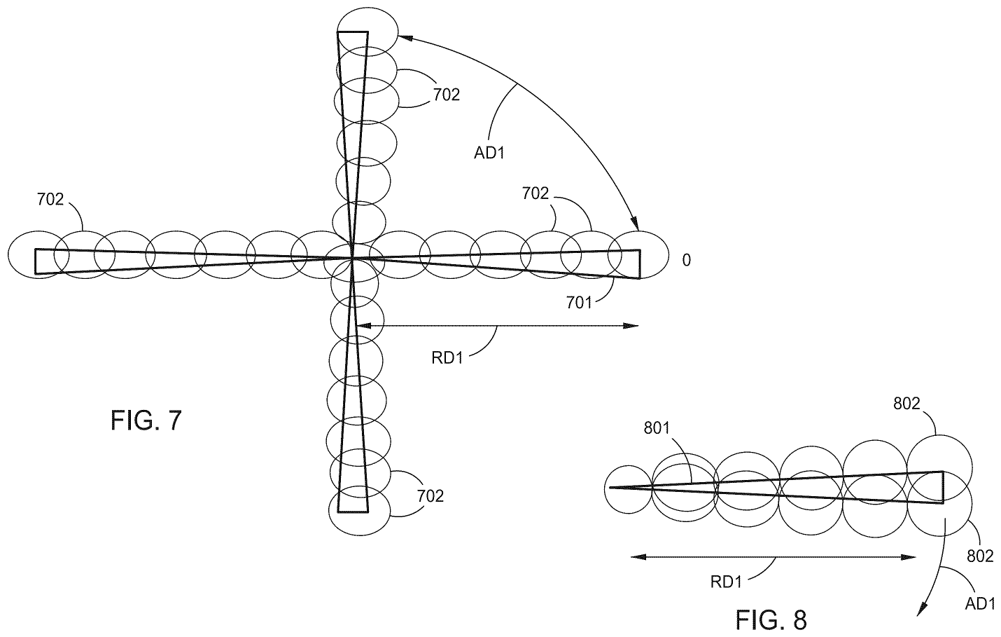

FIG. 7 is a schematic plan view of a spot path of radiation emitted by the heat assembly 200 shown in FIGS. 2 and 3, according to one or more embodiments.

The reflectors 201, 208 can be respectively pivoted to move the emitted radiation along a travel path 701. The radiation can be emitted as beam spots 702 along the travel path 701. For example, the first actuator 211 can pivot the first reflector 201 to move the beam spots along an azimuthal direction AD1, and the second actuator 213 can pivot the second reflector 208 to move the beam spots along a radial direction RD1. Using the reflectors 201, 208, a spot beam can move across an entirety of a substrate surface, which can have a variety of shapes.

FIG. 8 is a schematic plan view of a spot path of radiation emitted by the heat assembly 200 shown in FIGS. 2 and 3, according to one or more embodiments. The spot path in FIG. 8 is a portion of the spot path in FIG. 7.

The reflectors 201, 208 can be respectively pivoted to move the emitted radiation along a travel path 801. The radiation can be emitted as beam spots 802 along the travel path 801. The beam spots 802 can overlap such that locations receive multiple spots of radiation.

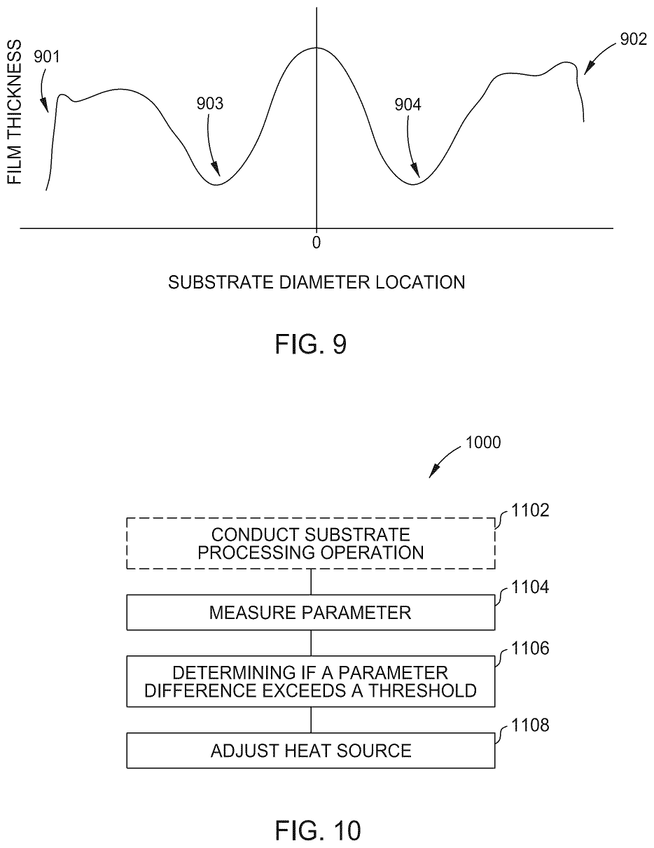

FIG. 9 is a schematic graphical view of a film thickness profile of a processed substrate. The film thickness profile can be measured, for example, along a linear line that extends through a center of the substrate 102 shown in FIG. 1, and extends across a diameter of the substrate 102 shown in FIG. 1. The film thickness profile includes locations 901-904 of non-uniformity where the film thickness drops off. The heat assembly 200 can be used to correct radially outward locations 901, 902 of non-uniformity, and/or the heat assembly 200 can be used to correct radially inward locations 903, 904 of non-uniformity.

FIG. 10 is a schematic flow diagram view of a method 1000 of monitoring substrate processing, according to one or more embodiments.

Optional operation 1002 includes conducting a substrate processing operation in a process chamber. The substrate processing operation may include a deposition process on a substrate and/or an etching process on the substrate. The substrate processing operation may further include heating the substrate, introducing at least one process gas, introducing a purge gas, and evacuating the process and purge gases. A single substrate or a plurality of substrates can be processed during the substrate processing operation.

Operation 1104 includes measuring a parameter of substrate processing. The parameter can be, for example, a film thickness and/or a temperature in a processing volume of the process chamber. In one or more embodiments, the film thickness and/or the temperature are measured on the substrate. In one or more embodiments, the film thickness and/or the temperature are determined across one or more of a plurality of azimuthal locations or a time interval. In one or more embodiments, the film thickness and/or the temperature are determined across one or more of a plurality of radial locations (such as from a center to the substrate to the edge of the substrate).

Operation 1106 includes determining if a parameter difference exceeds a threshold. The parameter difference corresponds to a location in a processing volume of a process chamber. In one or more embodiments, the threshold is an average of the film thickness or the temperature measured at a substrate location (such as a radial location) across a rotation of the substrate. In one or more embodiments, the threshold is an average of the film thickness or the temperature measured across a radial dimension of the substrate. The radial dimension can extend across an outer diameter of a processed substrate and through a center of the substrate. In one or more embodiments, the film thickness difference and/or the temperature difference are calculated based on a target thickness.

Operation 1108 includes adjusting a heat assembly (such as a heat assembly including a laser source) if the parameter difference exceeds a threshold. The adjustment of the heat assembly adjusts the parameter difference to be at or under the threshold. The adjustment can correct a non-uniformity of film deposited on the substrate. In one or more embodiments, the pivoting of the reflector rasterizes a target location of the radiation. The pivoting can, for example, rasterize structures on a surface of the substrate 102.

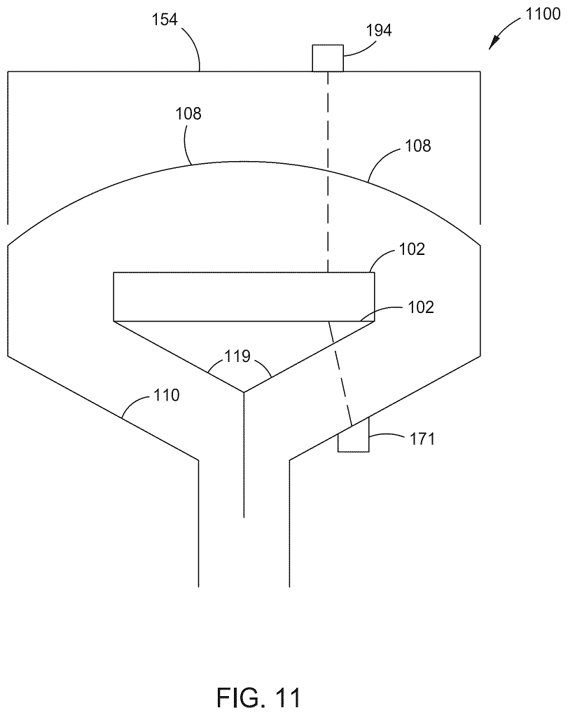

FIG. 11 is a schematic partial side cross-sectional view of a processing chamber 1100, according to one or more embodiments.

While FIG. 1 illustrates a single substrate 102 on a support, it is contemplated that a substrate support may support multiple substrates (e.g., two substrates) in a stacked, but spaced apart, configuration. In such an example, the heat assembly 194 can provide thermal radiation to the upper substrate 120, and the lower heat assembly 171 proves thermal radiation to the lower substrate 102. FIG. 11 illustrates such an example.

It is contemplated that while process chambers for epitaxial deposition are shown and described herein, the subject matter of the present disclosure is also applicable to other process chambers that are capable of providing a controlled thermal cycle that heats the substrate for processes such as, for example, thermal annealing, thermal cleaning, thermal chemical vapor deposition, thermal oxidation and thermal nitridation, regardless of whether the heating elements are provided at the top, bottom, or both the top and bottom of the process chamber.

Benefits of the present disclosure include adjustability of parameters (such as temperatures and/or film thickness) across a variety of operation conditions; reduced temperature non-uniformities; reduced deposition non-uniformities; enhanced film growth rates (e.g., at outer regions of substrates); enhanced device performance; limited parametric yield; increased chamber component lifespans; reduced cleaning; reduced chamber downtime; and increased throughput. Benefits also include cost reductions, increased substrate quality, scrap reductions, precise local heating of the substrate for ultra-fine adjusting of temperature uniformity, decreased bulk, increased lifetimes, less wearing, and mitigated sealing issues. The subject matter herein may, depending on application, be used to facilitate non-uniformities. For example, the one or more heat assemblies 194, 198 can facilitate temperature non-uniformities in the form of hot spots or cold spots.

Benefits further include rasterizing across the substrate surface, improving processing speed and providing a wider range of processing regimes; and processing based on heat maps, providing for more precise heating control.

The use of rasterizable spot heaters, such as those including galvanometers, rotating mirrors, rotating prisms, and the like, provides for responsive and adaptable heating of substrates for uniform processing. The rasterizing ability reduces the bulk of the device, and increases speed, thereby allowing greater substrate area coverage with less hardware. Particular scanning patterns can be based on substrate heat maps for incoming substrates. The heat maps be addressed by heating cool spots (and omitting to heat hot spots) using devices herein. Stated otherwise, the spot heaters can be selectively turned on and off to provide heat at desired locations while rasterizing or scanning across a rotating substrate. The apparatuses described herein can address non-circular (e.g., less than 360 degrees around a substrate at a particular radial position) hot or cold spots.

The apparatus of the present disclosure provides for multiple rasterizing schemes to improve thermal treatment uniformity. For example, the raster speed could be non-constant, the energy dose could be non-uniform depending upon substrate impingement position, the raster lengths could be varied at radial positions to result in more uniform energy delivery densities, or a combination of the preceding may be implement. In addition, it is contemplated that the spot size (e.g., surface area) of the thermal radiation may be adjusted by adjusting the path length of the radiation delivered to the substrate. The path length adjustment may be accomplished by moving the position of the radiation source 205 or a motion mechanism (such as the actuator 211). Additionally or alternatively, one or more reflective surfaces such as mirrors, may be positioned (e.g., selected actuated) to increase the path length prior to delivery of the thermal energy to the substrate.

It is contemplated that one or more aspects disclosed herein may be combined. As an example, one or more aspects, features, components, operations and/or properties of the processing chamber 100, the controller 190, the heat assembly 200, the heat assembly 400, the reflector plate 500, the reflector plate 600, the travel path shown in FIG. 7, the travel path shown in FIG. 8, the method 1000, and/or the processing chamber 1100 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A process chamber, comprising:
a chamber body at least partially defining a processing volume;
a substrate support disposed in the processing volume;
a heat assembly disposed outwardly of the processing volume, the heat assembly operable to direct radiation to a target location in the processing volume, and the heat assembly comprising:
a reflector pivotable relative to an axis to move the target location and scan the radiation, and
a radiation source oriented to emit the radiation toward the reflector.

2. The process chamber of claim 1, wherein the heat assembly further comprises:
a second reflector oriented to receive a reflected radiation from the reflector and reflect the reflected radiation to the target location in the processing volume, the second reflector pivotable relative to a second axis, and the second axis oriented nonparallel to the axis.

3. The process chamber of claim 2, wherein the reflector includes a first mirror and the second reflector includes a second mirror.

4. The process chamber of claim 1, wherein the heat assembly further comprises:
a first actuator comprising a first link coupled to the reflector along the axis.

5. The process chamber of claim 1, further comprising:
a controller operable to control the heat assembly based on one or more parameters, the one or more parameters comprising one or more of: a real-time measurement, a substrate map value, or a variation of substrate maps, the controller comprising instructions that, when executed, cause an input to be adjusted.

6. The process chamber of claim 5, wherein the input includes one or more of:
a first position angle for the reflector; or
a first angular velocity for the reflector.

7. The process chamber of claim 5, wherein the input includes one or more of:
a dwell time;
a radiation power for the radiation source; or
a pulse frequency for the radiation source.

8. The process chamber of claim 5, wherein the controller is configured to:
determine if a parameter difference exceeds a threshold; and
adjust the input if the parameter difference exceeds the threshold.

9. The processing chamber of claim 1, further comprising a reflector plate disposed outwardly of the processing volume, wherein the heat assembly comprises a reflector housing mounted to the reflector plate.

10. A process chamber, comprising:
a chamber body at least partially defining a processing volume;
a substrate support disposed in the processing volume;
a heat assembly disposed outwardly of the processing volume, the heat assembly comprising:
a polygonal reflector pivotable relative to an axis,
a radiation source oriented to emit radiation toward at least one outer surface of the polygonal reflector, the polygonal reflector oriented to reflect the radiation to a target location in the processing volume, and the polygonal reflector pivotable to move the target location.

11. The process chamber of claim 10, wherein the axis extends parallel to a plane of the at least one outer surface.

12. The process chamber of claim 10, wherein the polygonal reflector is rotatable about the axis.

13. The process chamber of claim 10, wherein the polygonal reflector includes a prism.

14. The process chamber of claim 10, wherein the at least one outer surface is a mirror surface.

15. The process chamber of claim 10, wherein the polygonal reflector includes a plurality of outer surfaces, and at least two of the outer surfaces have differing lengths.

16. The process chamber of claim 15, wherein the axis extends through two opposing outer surfaces of the polygonal reflector.

17. A method of monitoring substrate processing, comprising:
measuring a parameter of substrate processing;
determining if a parameter difference exceeds a threshold, the parameter difference corresponding to a location in a processing volume of a process chamber;
adjusting a heat assembly if the parameter difference exceeds a threshold, the heat assembly comprising:
a reflector pivotable relative to an axis,
a radiation source oriented to emit radiation toward the reflector.

18. The method of claim 17, further comprising rotating a substrate in the processing volume, wherein the adjusting comprises:
pivoting the reflector to rasterize a target location of the radiation during the rotation of the substrate.

19. The method of claim 18, wherein the pivoting rotates the reflector about the axis.

20. The method of claim 18, wherein the pivoting moves an incidence of the radiation from a first outer surface of the reflector to a second outer surface of the reflector, the second outer surface oriented at an angle relative to the first outer surface
